(19) United States
(12) Patent Application Publication
(10) Pub. No.: US 2016/0060752 A1
(43) Pub. Date: Mar. 3, 2016

(54) METHOD FOR PRODUCING A COMPOSITE MATERIAL WITH A CARBIDE MATRIX

(71) Applicants: HERAKLES, Le Haillan (FR); COMMISSARIAT A L'ENERGIE ATOMIQUE ET AUX ENERGIES ALTERNATIVES, Paris (FR); CENTRE NATIONAL DE LA RECHERCHE SCIENTIFIQUE, Paris (FR)

(72) Inventors: Sylvain JACQUES, Talence (FR); Olivier LEDAIN, Pessac (FR); Laurence MAILLE, Pessac (FR); Adrien DELCAMP, Merignac (FR); Thierry PIQUERO, Fondettes (FR)

(21) Appl. No.: 14/785,142

(22) PCT Filed: Apr. 10, 2014
(86) PCT No.: PCT/FR2014/050868

§ 371 Date: Oct. 16, 2015

(30) Foreign Application Priority Data
Apr. 19, 2013 (FR) 1353623

(51) Int. Cl. C23C 16/02; C04B 35/56; C23C 16/34; C04B 35/628; C23C 16/455; C23C 16/32; C04B 35/565; C04B 35/80

(52) U.S. Cl. CPC C23C 16/0272; C04B 35/565; C04B 35/5611; C04B 35/5607; C04B 35/806; C04B 35/62884; C23C 16/0209; C23C 16/45557; C23C 16/325; C23C 16/32; C23C 16/34

(57) ABSTRACT

A method of densifying a porous substrate with a matrix, includes subdividing the pores present in the porous substrate so as to form in the substrate a network of micropores, the subdividing being performed with a filler composition comprising at least one carbon-containing phase or carbide-containing phase that is accessible via the network of micropores; and infiltrating the network of micropores formed by the filler material by reactive chemical vapor infiltration, the infiltration being performed with a reactive gas composition that does not contain carbon and that includes at least one element suitable for reacting with the carbon of the filler composition in order to form a carbide.

### BACKGROUND OF THE INVENTION

The present invention relates to a method of densifying a porous substrate with a matrix presenting a continuous carbide phase. The invention applies particularly but not exclusively to making parts out of ceramic matrix composite (CMC) material formed by refractory fiber reinforcement (carbon or ceramic fibers) densified with a matrix that is ceramic, at least in part. Examples of CMCs are C/SiC composites (carbon fiber reinforcement and silicon carbide matrix), C/C—SiC composites (carbon fiber reinforcement and matrix comprising both a carbon phase, generally closer to the fibers, and a silicon carbide phase), and SiC/SiC composites (both reinforcing fibers and matrix made of silicon carbide).

Numerous techniques exist for densifying porous substrates enabling an at least partially carbide matrix to be formed within the substrate. These techniques include in particular:

a) Chemical vapor infiltration (CVI) which consists in infiltrating a gas mixture containing all of the elements forming the material into a porous preform in order to densify it. CVI deposits material at a constant rate over time. It is a method that imparts good properties to the material. Nevertheless, in order to obtain a uniform carbide matrix, while avoiding premature clogging at the periphery of the preform, it is necessary to work at low pressure and at relatively low temperature (≦1100° C.) in order to slow down the growth rate. That leads to long fabrication times for parts when using this technique, which makes the method expensive. It is sometimes necessary to perform machining in order to reopen peripheral pores and allow gas to access the core.

b) The liquid technique, which consists in impregnating a porous preform with a liquid composition, containing an organic precursor of the carbide material of the matrix, and possibly also including a filler. The organic precursor is generally in the form of a polymer, such as a resin, possibly diluted in a solvent. The precursor is transformed into a refractory phase by heat treatment, after eliminating the solvent if any and after cross-linking the polymer. The heat treatment consists in pyrolyzing the organic precursor in order to transform the organic matrix into a ceramic matrix that depends on the precursor in use and on the conditions of pyrolysis. Nevertheless, the material generally presents residual porosity as a result of material shrinkage during pyrolysis.

c) The liquid metal technique (reactive melt infiltration (RMI), melt infiltration (MI), liquid silicon infiltration (LSI), . . . ), which consists in introducing a molten metal (e.g. Si at high temperature (>1400° C.)) into a porous preform that generally contains a powder or a porous material (e.g. C with or without SiC) that reacts with the metal in order to form the final matrix material. A fraction of the metal not reacting with the powders present in the preform leads to the presence of residual free metal within the final matrix (e.g. free silicon), and that can lead to oxidation within the material and consequently to a degradation in the properties of the fibers. A so-called “choking-off” effect can also prevent certain pores from being filled in.

d) The ceramic or ceramic slip technique, which consists in impregnating fiber preforms with a slip (a mixture of ceramic particles of submicrometer size, of sintering additives, and of water) and then drying and sintering the impregnated preform at a temperature in the range 1600° C. to 1800° C. under pressure, as described in particular in Document EP 0 675 091. That method can nevertheless be applied only to unidirectional CMC materials, in particular because of the shrinkage of the matrix during sintering, and in addition the additives are harmful for the final properties of the material.

The Document by Vincent et al. (H. Vincent, J. L. Ponthenier, L. Porte, C. Vincent, and J. Bouix entitled “Influence des conditions experimentales du depot de SiC par RCVD sur l'infiltration de substrats de carbone poreux” [The influence of experimental conditions on SiC deposition by RCVD on the infiltration of porous carbon substrates], Journal of the Less Common Metals, 157 (1990), 1-13) describes reactive chemical vapor deposition (RCVD) for infiltrating porous solid graphite substrates or substrates made of non-agglomerated or compacted powder with SiC. When powder is used, the purpose is not to consolidate but rather to modify the surfaces of the particles in order to protect them from oxidation. In the document by Bouix et al. (J. Bouix, J. C. Viala, H. Vincent, C. Vincent, J. L. Ponthenier, and J. Dazord entitled “Process for coating carbon fibers with a carbide”, U.S. Pat. No. 4,921,725 (A)—May 1, 1990), RCVD is also used for coating carbon fibers with a protective carbide layer, but without thereby densifying the preform.

The Document by Tang et al. (S. F. Tang, J. Y. Deng, S. J. Wang, W. C. Liu, and K. Yang entitled “Ablation behaviors of ultra-high temperature ceramic composites”, Materials Science and Engineering A 465 (2007) 1-7), describes making composite materials from raw compacts of micrometer powders of ZrB₂, SiC, HfC, and TaC consolidated by pyrolytic carbon CVI. Under such circumstances, the continuous matrix phase is not made of carbide, but rather of pyrolytic carbon, a phase that is sensitive to the environment. The same authors have already made composites from 1.5 micrometer (μm) ZrB₂ powder consolidated with SiC (S. F. Tang, J. Y. Deng, S. J. Wang, and W. C. Liu entitled “Fabrication and characterization of an ultra-high temperature carbon fiber-reinforced ZrB₂—SiC matrix composite”, Journal of the American Ceramic Society 90 (2007) 3320-3322) using a variant of CVI referred to as heaterless chemical vapor infiltration (HCVI).

None of those presently available densification techniques provides a satisfactory solution for obtaining densification of porous substrates both rapidly and uniformly throughout the substrate, and using a matrix that has a carbide phase that is continuous, i.e. without any free metal.

### OBJECT AND SUMMARY OF THE INVENTION

A particular object of the present invention is to respond to the above-specified drawbacks. This object is achieved by a method of densifying a porous substrate with a matrix, said method comprising the steps of:
subdividing the pores present in the porous substrate so as to form in said substrate a network of micropores, said subdividing being performed with a filler composition comprising at least one carbon-containing phase or carbide-containing phase that is accessible via the network of micropores; and
infiltrating the network of micropores formed by the filler material by reactive chemical vapor infiltration, the infiltration being performed with a reactive gas composition that does not contain carbon and that includes at least one element suitable for reacting with the carbon of the filler composition in order to form a carbide.

Thus, with the method of the invention, densification can be accelerated by filling and subdividing the large pores initially presented by the substrate in a first step, while still ending up with good and uniform densification throughout the micropores of the material by reactive chemical vapor infiltration in a second step. The carbide layer formed by reaction between the carbon or carbide phase of the filler composition and the reactive gas composition that is infiltrated into the substrate grows locally at a growth rate that is parabolic, i.e. the thicker it becomes the slower it grows. Consequently, at the beginning of infiltration, the carbide layer is thicker on the portions of the filler composition that are situated at the periphery of the substrate than on the portions situated more deeply in the substrate. Nevertheless, since the growth of the carbide layer slows down initially for the filler composition situated at the periphery of the substrate, the substrate does not become prematurely clogged at its surface, thereby enabling the reactive gas composition to penetrate to the core of the substrate as infiltration continues. In addition, in spite of the concentration gradient in the reactive gas composition between the periphery and the core of the substrate, the carbide layer formed at the core of the substrate ends up being as thick as the carbide layer present at the periphery of the substrate, which cannot be obtained with conventional CVI, i.e. non-reactive CVI, where the depletion of the gas phase as it penetrates more deeply into the substrate limits the thickness of the deposited matrix layer. In the present invention, the carbide layer is formed by reaction between the infiltrated gas composition and the carbon of the filler composition, which implies not only diffusion of the gas phase, but also solid phase diffusion of the carbon present in the filler composition, thereby compensating for the concentration gradient. Thus, at the end of infiltration, the substrate is densified in a manner that is uniform throughout its depth.

In a first aspect of the invention, the method further comprises making a fiber structure corresponding to the porous substrate that is to be densified. The method of the invention then makes it possible to fabricate a composite material of the type comprising fiber reinforcement densified by a carbide matrix. When making a CMC material, the fiber structure is made from carbon fibers or from silicon carbide fibers.

In a second aspect of the method of the invention, the subdividing of the pores comprises introducing a powder into the porous substrate, the powder being constituted by micrometer or submicrometer particles of carbon-containing or carbide-containing material, or including at least a surface layer of carbon-containing or carbide-containing material.

In a third aspect of the method of the invention, the subdividing of the pores comprises impregnating the porous substrate with a liquid precursor for carbon or carbide, or for a carbon-containing or carbide-containing material, and transforming the precursor by pyrolysis.

In a fourth aspect of the method of the invention, the subdividing of the pores comprises forming in the porous substrate an aerogel or xerogel of a precursor material for carbon or carbide or for a carbon-containing or carbide-containing material, and transforming the precursor by pyrolysis.

In a fifth aspect of the method of the invention, the reactive gas composition comprises at least one of the reactive elements selected from: titanium, zirconium, hafnium, tantalum, silicon, and boron. The reactive gas composition may in particular comprise at least one halide gas selected from at least: TiCl₄, ZrCl₄, HfCl₄, SiH₄, TaI₄, TaCl₅, SiCl₄, BCl₃, and BF₃.

In a sixth aspect of the method of the invention, the reactive chemical vapor infiltration is performed under pulsed pressure.

In a seventh aspect of the invention, the method comprises, prior to subdividing the pores, forming a layer of a carbide or of pyrolytic carbon on the fibers of the fiber structure. It may also comprise forming a layer of nitride having no carbon on the layer of carbide or of pyrolytic carbon formed on the fibers of the fiber structure.

### BRIEF DESCRIPTION OF THE DRAWINGS

Other characteristics and advantages of the invention appear from the following description of particular implementations of the invention, given as non-limiting examples, and with reference to the accompanying drawings, in which:

FIGS. 1A to 1C are diagrammatic views showing how densification of a powder substrate of carbon grains progresses when performed by reactive chemical vapor infiltration;

FIG. 2 plots curves showing how the carbon particle conversion ratio varies during the densification of the substrate of FIGS. 1A to 1C as a function of the positions of particles in the substrate;

FIG. 3 is a flow chart showing the steps of a densification method in an implementation of the invention;

FIGS. 4A and 4B are diagrammatic views showing a fiber structure densified in compliance with the steps of FIG. 3;

FIGS. 5A to 5C are photographs showing the results obtained in the vicinity of the periphery of a fiber preform during different stages of its reactive chemical vapor infiltration;

FIGS. 6A to 6C are photographs showing the results obtained at an intermediate depth in a fiber preform at different stages of its reactive chemical vapor infiltration;

FIGS. 7A to 7C are photographs showing the results obtained at the core of a fiber preform at different stages of its reactive chemical vapor infiltration; and

FIG. 8 is a photograph showing a fiber preform impregnated with a filler composition prior to reactive chemical vapor infiltration.

### DETAILED DESCRIPTION OF IMPLEMENTATIONS

The present invention proposes a method of densifying a porous substrate with a carbide matrix obtained by reactive chemical vapor infiltration (RCVI) performed using a reactive gas composition having no carbon and suitable for reacting with carbon that is present in the substrate in order to form one or more carbides.

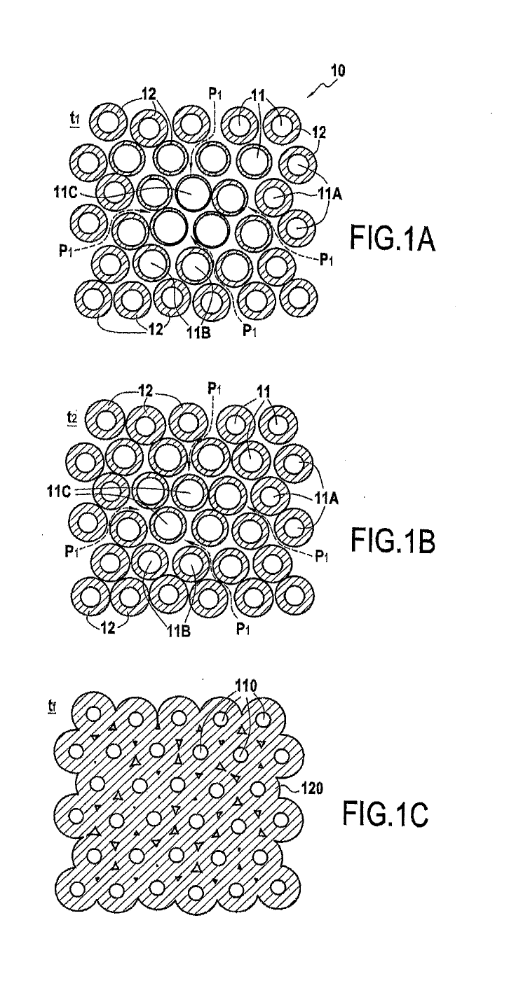

FIGS. 1A to 1C show how RCVI densification progresses in a porous substrate 10 constituted by a powder of carbon grains 11 of submicrometer size, i.e. of size less than one micrometer, or of micrometer size, i.e. of size greater than or equal to one micrometer. The powder is infiltrated with a reactive gas phase P1 suitable for forming at least one carbide by reaction between the carbon of the grains 11 and the gas phase P1. In the presently-described example, the reactive gas phase is constituted by TiCl₄ that, on contact with grains of carbon, serves to form a titanium carbide (TiC) matrix. The carbide layer grows locally around each carbon-containing grain or particle, namely by solid phase diffusion of carbon, and possibly of other elements, from the particle of the initial substrate to the surface of the carbide layer that is growing. This mechanism implies that the carbon-containing particles are consumed while being converted into new carbide.

At the beginning of infiltration, and as shown in FIG. 1A, the gas phase P1 flowing throughout the substrate 10 reacts preferentially with the carbon grains 11A that are situated at the periphery of the substrate 10, the TiC layer 12 formed on the grains 11 being thicker on grains 11A situated between the periphery of the substrate 10 than on grains 11B situated at the core of the substrate and at its periphery, and above all on the grains 11C situated at the core of the substrate 10.

As infiltration continues, and as shown in FIG. 1B, the growth of the TiC layer slows down on the grains 11A, whereas it starts and is maintained without slowing down on the grains 11B and then 11C. This progress in growth between the periphery and the core of the substrate during RCVI is due to the growth rate of the carbide layer following a parabolic curve. Local growth of the carbide layer slows down in proportion to the increase in the thickness of the layer that has already been formed, since the mechanism whereby carbon diffuses in solid phase becomes limiting.

For a reactive gas phase constituted by TiCl₄, the temperature to which the substrate is heated is selected to lie in the range 800° C. to 1200° C., which makes it possible to avoid being limited by the chemical reaction, while still enabling the phenomenon of carbide layer growth slowing down to occur at the scale of pore size.

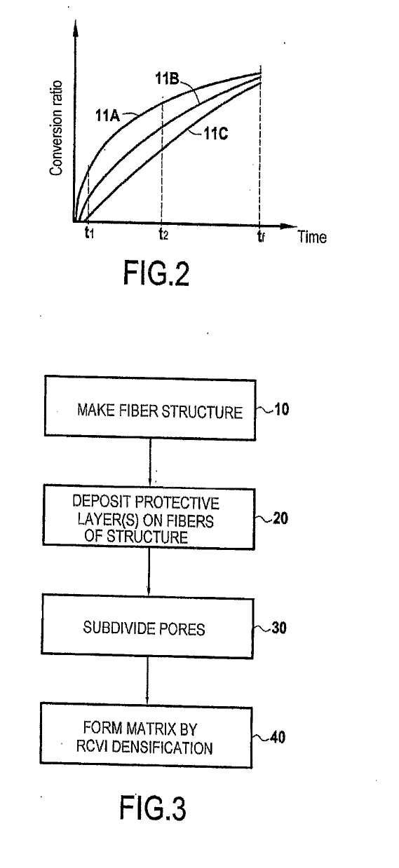

In general, an infiltration temperature is selected as a function of the reactivity of the gas phase so as to obtain a slowdown in growth that makes it possible to avoid premature clogging at the periphery of the porous substrate as a result of a layer that is too thick, and on the contrary, so as to encourage rapid growth of the layer that would otherwise remain thin in the pores that are present at the core of the substrate, given the concentration gradient of the reactive gases. This automatic balancing thus arises because of two different transport mechanisms. The first transport mechanism is in the gas phase and it operates at the scale of the thickness of the substrate (several millimeters), where the gradient of gas reactive species between the core and the periphery is compensated by the second transport mechanism, which is in the solid phase, and at the local scale of pore size (submicrometric or micrometric). The carbon grain conversion ratio as a function of grain position within the porous substrate and as a function of infiltration time is shown in FIG. 2, which shows clearly that the growth of the carbide layer of grains 11A situated at the periphery of the substrate is automatically controlled by solid diffusion of carbon, whereas the growth of the layer on grains 11C situated at the core of the substrate is automatically controlled by depletion of the reactive gas.

The parabolic growth rate and the automatic balancing obtained by the different transport mechanisms at the periphery and at the core make it possible to obtain uniform densification of the substrate as shown in FIG. 1C where it can be seen that, at the end of RCVI, the substrate 10 is densified in uniform manner by a TiC matrix 120, both at the periphery and at the core, the TiC matrix 120 being present around particles 110 that are fine and that correspond to the non-consumed residue of the carbon grains 11.

The method of the invention is particularly, but not exclusively, applicable to densifying porous substrates such as foams, powders, and fiber preforms for use in fabricating parts made out of composite material, and in particular made out of CMC material.

Prior to the RCVI step, the method of the invention includes a step of subdividing the pores of the substrate, which step consists in introducing a filler composition into the substrate, which filler may in particular comprise:
a powder constituted by micrometric or submicrometric particles of carbon-containing or carbide-containing material, or including at least a surface layer of carbon-containing material;
a liquid precursor for carbon or carbide, or for a carbon-containing or carbide-containing material, that is subsequently transformed by pyrolysis; or
an aerogel or xerogel made of a material that is a precursor of carbon or carbide or of a carbon-containing material or of a carbide-containing material, which precursor material is subsequently transformed by pyrolysis.

The subdividing step makes it possible to form a network of micropores within the substrate, i.e. a plurality of communicating pores, each of a size lying in the range a few nanometers to a few micrometers.

The RCVI step seeks to cause new carbides to grow within the network of micropores formed by the filler material constituted by carbon or by carbide. For this propose, as with RCVD, a reactive gas is used that is made up of molecules comprising at least one element that is suitable for reacting with the carbon in solid phase. In accordance with the invention, the reactive gas composition used for RCVI does not contain the element carbon. The ultimate purpose of the RCVI is to densify the network of micropores.

In the RCVI performed in the present invention, the molecules of the gas in the gas composition react with one another and/or decompose in order to release the reactive element at the surface of the solid carbon or carbide phase present within the network of micropores. Simultaneously, the element that has been released reacts with the carbon of the initial solid phase so as to form the new carbide. This phenomenon can continue because of the carbon that diffuses in the solid phase through the new carbide from the initial carbon or carbide phase towards the surface (locally inside pores). The initial carbon or carbide phase is consumed progressively and transformed into new carbide.

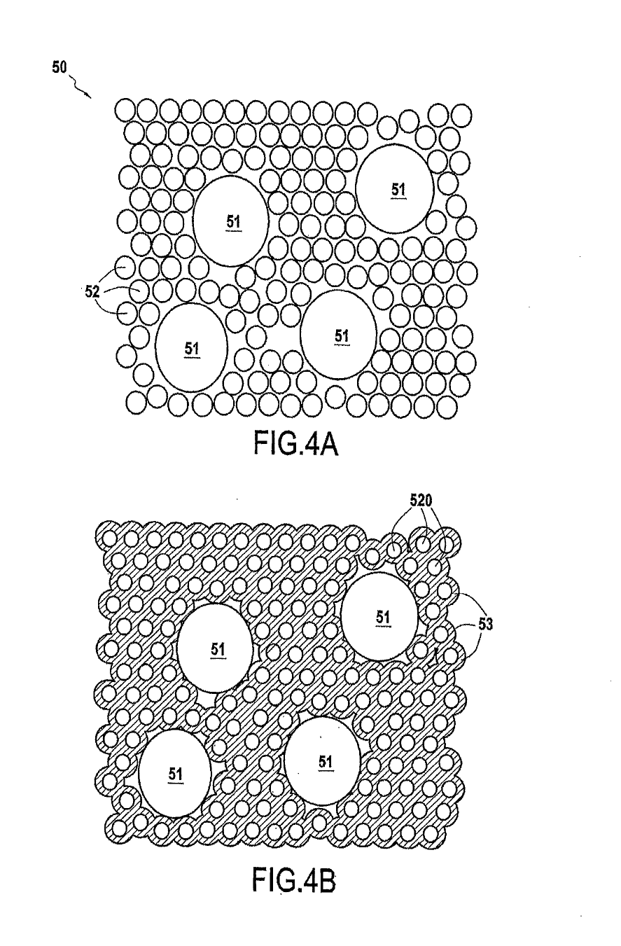

An implementation of the method of the invention as applied to fabricating a composite material part is described with reference to FIGS. 3, 4A, and 4B.

The method of fabricating a composite material part begins by making a fiber structure (step 10).

The fiber structure may be of various forms, such as:
a two-dimensional (2D) woven fabric;
a three-dimensional (3D) woven fabric obtained by 3D weaving or as multiple layers;
a braid;
a knitting;
a felt; or
a unidirectional (UD) sheet of multidirectional (nD) yarns, or tows, or sheets obtained by superposing a plurality of UD sheets in different directions and bonding the UD sheets together, e.g. by stitching, by a chemical bonding agent, or by needling.

It is also possible to use a fiber structure made up of a plurality of superposed layers of fabric, braid, knitting, felt, sheets, etc., which layers are bonded together, e.g. by stitching, by implanting yarns or rigid elements, or by needling.

The fibers constituting the fiber structure are refractory fibers, i.e. fibers made of ceramic, e.g. of silicon carbide (SiC), carbon fibers, or indeed fibers made of a refractory oxide, e.g. of alumina (Al₂O₃).

The fibers may optionally be coated in an interphase, e.g. constituted by one or more layers of pyrolytic carbon (PyC), of boron-doped carbon (BC), or of boron nitride (BN).

In the presently-described example, the fiber structure is made as a single piece by three-dimensional or multilayer weaving of carbon fiber yarns, as described in particular in Document WO 2010/061140.

In accordance with the method of the invention, the pores present in the porous substrate, in this example the fiber structure, are initially subdivided with a filler material comprising at least a carbon-containing phase and/or a carbide-containing phase that is accessible via the network of micropores so as to form a network of micropores in said substrate (step 30). The filler material may in particular be constituted by submicrometer or micrometer grains or particles of carbon-containing or carbide-containing material or grains coated in such a material (grains of “core-shell” structure) present in the form of a suspension in a liquid.

For porous substrates containing carbon-containing or carbide-containing ingredients, as applies in particular with fiber structures comprising carbon fibers, silicon carbide fibers, fibers coated in a pyrolytic carbon interphase, etc., the substrate is previously treated so as to protect those ingredients from subsequent reactions during the reactive chemical vapor infiltration step (step 20). This protection may be obtained by predensifying the porous substrate by chemical vapor infiltration (CVI) using a carbide or pyrolytic carbon that then acts as a “sacrificial” layer during reactions with the gas phase(s) of the reactive chemical vapor infiltration. This protective layer may be reinforced by using CVI to deposit on the sacrificial layer a layer of nitride that contains no carbon, e.g. a layer of titanium nitride (TiN) or of zirconium nitride (ZrN), which acts as a “diffusion barrier” between the underlying carbon and the gas phase(s) used for reactive chemical vapor infiltration. In the presently-described example, the carbon fibers are coated in a layer of silicon carbide and in a layer of TiN, both of which are deposited by CVI.

The pores are subdivided in this example by transferring an aqueous slip into the fiber structure, which slip contains a powder of carbon particles of submicrometer or micrometer size. As shown in FIG. 4A, after drying, a fiber structure 50 is obtained in which the pores present between the fibers 51 are filled and subdivided to constitute a network of micropores by means of carbon particles 52. The volume fraction of the powder introduced into the preform lies in the range 25% to 75%. It is adjusted as a function of the desired final content of carbon-containing material and carbide-containing material, taking account of the consumption of carbon, and consequently of the conversion ratio of the particles as a result of RCVI.

Thereafter, RCVI is performed by infiltrating the fiber structure 50 with a reactive gas composition that does not contain any carbon and that contains one or more reactive elements selected in particular from titanium, zirconium, hafnium, tantalum, silicon, and boron. The reactive gas composition may comprise one or more halide gases selected in particular from TiCl₄, ZrCl₄, HfCl₄, SiH₄, TaI₄, TaCl₅, SiCl₄, BCl₃, and BF₃.

Examples of reactions between a solid carbon-containing or carbide phase and a reactive gas composition in accordance with the invention are given below;

TiCl₄(gas)+2H₂(gas)+C(solid)→TiC(solid)+4HCl(gas)

SiH₄(gas)+C(solid)→SiC(solid)+2H₂(gas)

TaI₄(gas)+SiC(solid)→TaC(solid)+SiI₄(gas)

Infiltration parameters such as temperature and pressure are adjusted as a function of the composition of the reactive gas phase. As explained above, the temperature is adjusted to be high enough to enable a reaction to take place between the gas composition and the carbon present on the particles, while making it possible for the phenomenon of the growth of the carbide layer slowing down to take place at micrometer or submicrometer scale corresponding to the scale of the micropores to be filled in. The gas composition is infiltrated into the porous substrate at a pressure lying in the range 1 millibar (mbar) to 1 bar. RCVI can also be performed using pulsed pressure (P-RCVI) in order to further improve the uniformity of infiltration.

At the end of RCVI, and as shown in FIG. 4B, a composite material 50 is obtained that comprises fiber reinforcement constituted by fibers 51 and densified by a carbide(s)/carbon matrix that is constituted mainly by one or more carbides 53 surrounding fine particles 520 corresponding to the non-consumed residues of the particles 52.

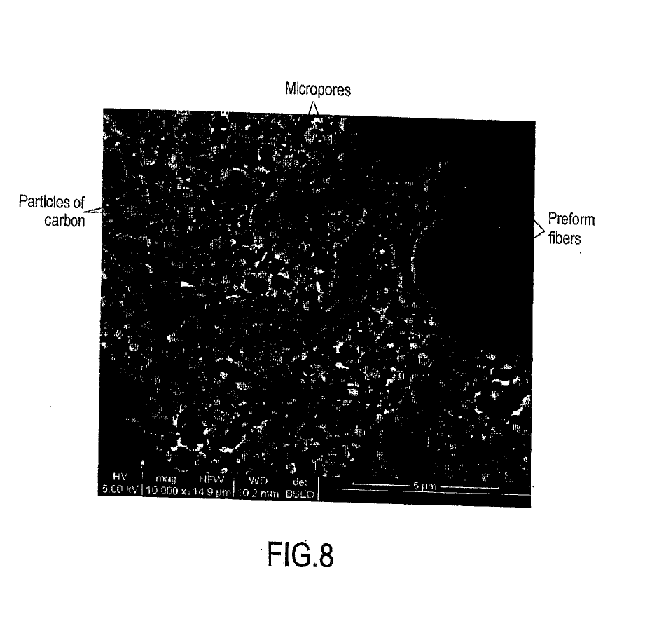

Tests have been performed on carbon fiber preforms having thickness of millimeter order, with the pores of the preform being subdivided by impregnating it by transfer using a filler composition comprising a powder of carbon particles having a mean diameter of 600 nanometers (nm) applied by means of an aqueous slip, the preform being dried at 70° C. after impregnation. FIG. 8 is a photograph taken with a scanning electron microscope using backscattered electrons showing the fiber preform impregnated with the filler composition prior to reactive chemical vapor infiltration. The fiber preform was then subjected to RCVI during which it was infiltrated with a gas phase constituted by a mixture of TiCl₄/H₂ gases so as to form a C/TiC matrix in the preform.

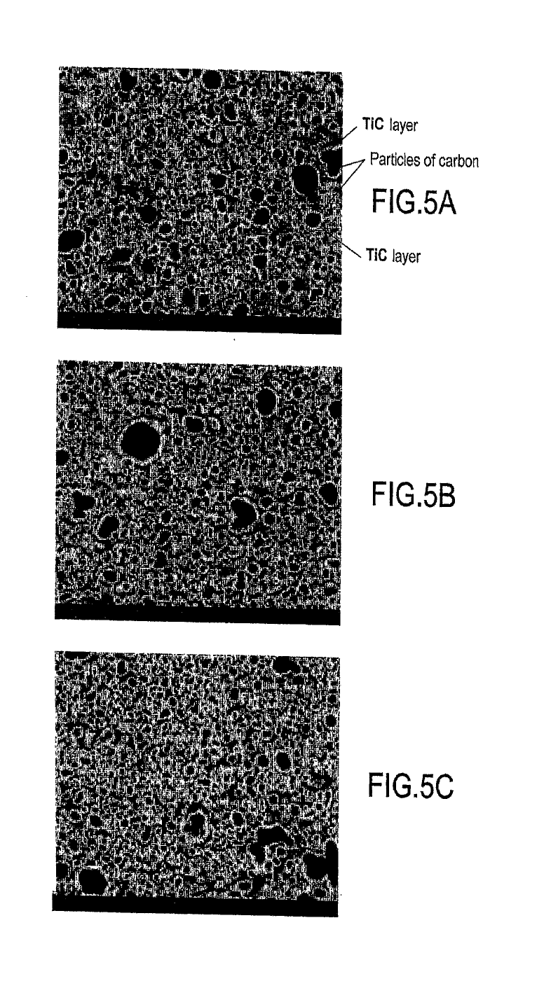

FIGS. 5A to 5C are photographs taken with a scanning electron microscope using backscattered electrons showing the result in the vicinity of the periphery of the preform (depth of 50 μm), respectively after 4 hours, 24 hours, and 36 hours of infiltration with a TiCl₄/H₂ gas mixture at 950° C. The black portions correspond to carbon, while the pale portions correspond to TiC.

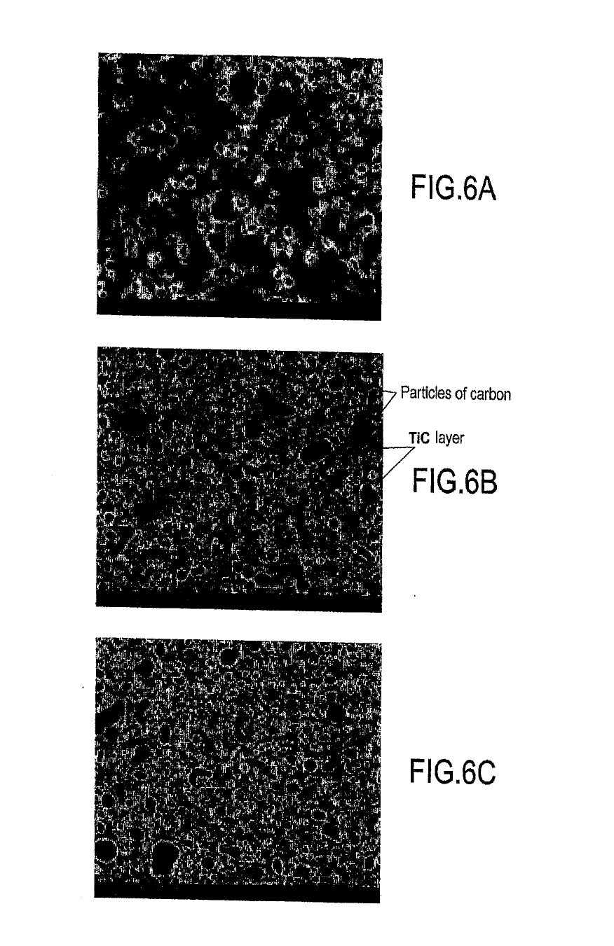

FIGS. 6A to 6C are photographs taken with a scanning electron microscope using backscattered electrons showing the result at an intermediate depth in the preform (depth of 150 μm) respectively after 4 hours, 12 hours, and 24 hours of infiltration with a TiCl₄/H₂ gas mixture at 950° C. The black portions correspond to carbon, while the pale portions correspond to TiC.

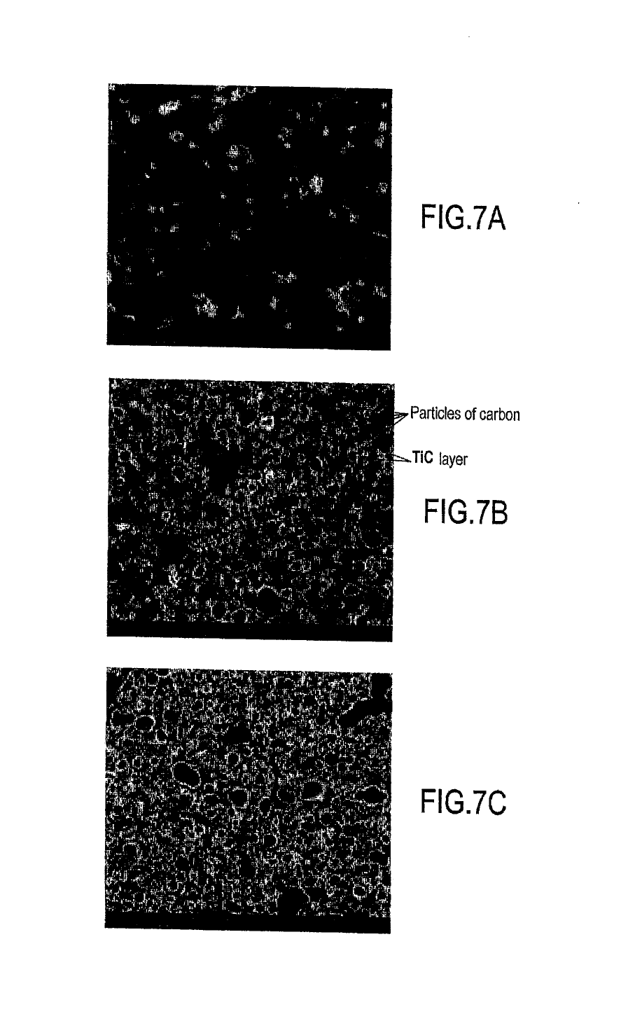

FIGS. 7A to 7C are photographs taken with a scanning electron microscope using backscattered electrons showing the result in the vicinity of the core of the preform (depth of 300 μm), respectively after 4 hours, 12 hours, and 18 hours of infiltration with a TiCl₄/H₂ gas mixture at 950° C. The black portions correspond to carbon, while the pale portions correspond to TiC.

As can be seen in the above-described photographs, even if the TiC carbide layer is of smaller thickness at the beginning of infiltration on carbon particles present below the periphery of the preform, this layer ends up being present with a uniform thickness throughout the preform at the end of infiltration.

1. A method of densifying a porous substrate with a matrix, said method comprising:
subdividing the pores present in the porous substrate so as to form in said substrate a network of micropores, said subdividing being performed with a filler composition comprising at least one carbon-containing phase or carbide-containing phase that is accessible via the network of micropores; and
infiltrating the network of micropores formed by the filler material by reactive chemical vapor infiltration, the infiltration being performed with a reactive gas composition that does not contain carbon and that includes at least one element suitable for reacting with the carbon of the filler composition in order to form a carbide.

2. A method according to claim 1, further comprising making a fiber structure corresponding to the porous substrate that is to be densified.

3. A method according to claim 2, wherein the fiber structure is made from carbon 25 fibers or from silicon carbide fibers.

4. A method according to claim 1, wherein the subdividing of the pores comprises introducing a powder into the porous substrate, the powder being constituted by micrometer or submicrometer particles of carbon-containing or carbide-containing material, or including at least a surface layer of carbon-containing or carbide-containing material.

5. A method according to claim 1, wherein the subdividing of the pores comprises impregnating the porous substrate with a liquid precursor for carbon or carbide, or for a carbon-containing or carbide-containing material, and transforming the precursor by pyrolysis.

6. A method according to claim 1, wherein the subdividing of the pores comprises forming in the porous substrate an aerogel or xerogel of a precursor material for carbon or carbide or for a carbon-containing or carbide-containing material, and transforming the precursor by pyrolysis.

7. A method according to claim 1, wherein the reactive gas composition comprises at least one of the reactive elements selected from: titanium, zirconium, hafnium, tantalum, silicon, and boron.

8. A method according to claim 7, wherein the reactive gas composition comprises at least one halide gas selected from at least: TiCl₄, ZrCl₄, HfCl₄, SiH₄, TaI₄, TaCl₅, SiCl₄, BCl₃, and BF₃.

9. A method according to claim 1, wherein the reactive chemical vapor infiltration is performed under pulsed pressure.

10. A method according to claim 2, wherein prior to subdividing the pores, the method comprises forming a layer of a carbide or of pyrolytic carbon on the fibers of the fiber structure.

11. A method according to claim 10, further comprising forming a layer of nitride having no carbon on the layer of carbide or of pyrolytic carbon formed on the fibers of the fiber structure.
